(19) United States
(12) Patent Application Publication
(10) Pub. No.: US 2018/0054926 A1
(43) Pub. Date: Feb. 22, 2018

(54) ELECTROMAGNETIC WAVE SHIELDING SHEET COMPRISING CARBON COMPOSITE FIBER MANUFACTURED BY ELECTROSPINNING AND METHOD FOR MANUFACTURING SAME

(71) Applicant: KOREA INSTITUTE OF INDUSTRIAL TECHNOLOGY, Cheonan (KR)

(72) Inventors: Hoon HUH, Cheonan (KR); Hui Jin Kim, Asan (KR); Su Jin Kim, Seoul (KR); Myung Chul Shin, Cheonan (KR); Jong Ho Lee, Seoul (KR); Choon Keun Park, Daejeon (KR)

(21) Appl. No.: 15/783,212

(22) Filed: Oct. 13, 2017

Related U.S. Application Data
(62) Division of application No. 14/892,602, filed on Nov. 20, 2015.

(30) Foreign Application Priority Data
May 21, 2013 (KR) 10-2013-0057044

(51) Int. Cl. H05K 9/00; D01D 5/00; D01F 8/18; D01F 1/10; D01F 9/14

(52) U.S. Cl. CPC H05K 9/009; D01D 5/003; D01F 9/14; D01F 8/18; D01F 1/106; D10B 2101/12

(57) ABSTRACT

An electromagnetic wave shielding sheet including a carbon composite fiber and manufactured by electrospinning, and a method of manufacturing the same are disclosed. More particularly, an electromagnetic wave shielding sheet includes a carbon composite fiber having a core-shell structure and a resin, and the core-shell structure includes an outer shell including a carbon fiber, and a core including metal nano particles arranged in a length direction of the carbon fiber in the outer shell. The electromagnetic wave shielding sheet includes metal nano particles as electromagnetic wave shielding materials in a carbon fiber, and the oxidation of a metal may be prevented, conductivity in a length direction of the carbon fiber may be secured, and the sheet may be applied to various industrial fields as an electromagnetic shielding material.

### CROSS-REFERENCES TO RELATED APPLICATION

This application is a Divisional Application of U.S. patent application Ser. No. 14/892,602 filed on Nov. 20, 2015, which is a National Stage application of PCT/KR2014/004516 filed on May 21, 2014, which claims priority to Korean Patent Application No. 10-2013-0057044 filed on May 21, 2013, the contents of which are incorporated herein by reference.

### TECHNICAL FIELD

The present invention relates to a sheet for shielding electromagnetic waves including carbon composite fibers prepared by electrospinning for improving conductivity and electromagnetic wave shielding efficiency and a method of manufacturing the same.

### BACKGROUND ART

Recently, industries requiring shielding measure are diversified according to the explosive increase of the diffusion of asymmetric digital subscriber line (ADSL) and the initiation of next generation cellular phone, intelligent transport system (ITS), etc. In addition, the rapid spread of personal computers (PC), cellular phones and digital instruments, which are miniaturizing and weight lightening cause the flood of electromagnetic waves in an office and at home, and the threatening of electromagnetic interference is increasing further along with the development of electronics industry.

The electromagnetic interference includes many cases from the malfunction of computers to the total destruction of a factory by fire, and worry and concern about health are increasing because of the reports on research results on negative effects of the electromagnetic waves to human body one after another. Accordingly, advanced countries are struggling to reinforce regulations and prepare a countermeasure on the electromagnetic interference. Therefore, techniques on shielding electromagnetic waves in diverse electric and electronic products are emerging as core technology field in electronics industry.

The shielding technology of electromagnetic waves is generally classified into two methods including a method of protecting an external equipment by shielding around the generating source of electromagnetic waves and a method of protecting an equipment from the external generating source of electromagnetic waves by storing in a shielding material. A method having the limelight uses the shielding material of electromagnetic waves.

However, limitations for solving with regard to the shielding performance, applicability, cost, etc. of the shielding material of electromagnetic waves are a lot, and studies thereon are necessary.

In addition, limitations on the reinforcement of a countermeasure on noise immunity, the increase of consumption on high frequency digital instruments, influence of low frequency electromagnetic waves on human body, etc. are internationally emerging, and the significance on the developments of the shielding material of electromagnetic waves with high performance is further increasing. Therefore, R&D activities are actively conducted by related domestic companies; however research infrastructure thereon is still insufficient.

Recently, demands on overall and reliable analysis information on interested main industries are increasing in each field including an industry-academic cooperation, etc.; however supplies via research and analysis institutions are insignificant.

Among materials for shielding electromagnetic waves, a metal material reflects the electromagnetic waves, while an insulating material including plastic transmits the electromagnetic waves. The shielding of the electromagnetic waves using a metal is widely known. When electromagnetic waves touch an electric conductor, a portion thereof may be absorbed or transmit, however the most thereof may be reflected. When electromagnetic waves touch a conductor, eddy current may be generated owing to electromagnetic induction in the conductor, and the eddy current may reflect the electromagnetic waves. In such a metal material, electromagnetic waves may be effectively blocked, however the manufacturing thereof by a die casting method may increase production costs and defect ratios.

A material absorbing the electromagnetic waves may include a material absorbing conductive electromagnetic waves, a material absorbing dielectric electromagnetic waves, a material absorbing magnetic electromagnetic waves.

The conductive material is a material absorbing electromagnetic waves by currents flowing through a resistor, a line of resistance, a resistor film, etc., and the selection of a material having an appropriate resistance value during using is significant. Excellent absorbent of electromagnetic waves may also be obtained by textiles manufactured using conductive fibers.

A dielectric material may include carbon, carbon-containing foamed urethane, carbon-containing foamed polystyrene, etc. In order to obtained broadband characteristics using such kind of absorbents, a multilayer structure is necessary to be formed so that attenuation near a surface may become small, and the attenuation may increase with the entrance to inwards.

For example, Korean Patent Publication No. 2010-0112744 discloses a shielding film of electromagnetic waves, which has a layer shape and is formed of carbon nanotubes and a binder and exhibiting the shielding performance of electromagnetic waves by the carbon nanotubes, wherein 3 to 15 wt % of the carbon nanotubes are mixed on the basis of the total amount of the carbon nanotubes and the binder, and a thickness of the film is from 2 mm to 5 mm, and a shielding article of electromagnetic waves, in which the shielding film of electromagnetic waves is attached to a panel by an adhesive agent.

Currently, conductive plastics for shielding electromagnetic waves are polymer-matrix composites containing conductive fillers obtained by mixing an electrically conductive filler such as a metal fiber and a carbon fiber with a general-purpose plastic matrix which is a nonconductive material, and a technical method of using the materials is being studied.

Korean Patent Publication No. 2007-0035832 discloses a method of manufacturing a transparent shielding material of electromagnetic waves including a step of producing a transparent base material in a solution state by dissolving at least one material of a transparent metal, ceramic or polymer in a solvent, a step of mixing at least one material of carbon nanotube (CNT), carbon nanofiber (CNF) or magnetic particles with a nano size in a certain amount for maintaining transparency, a step of dispersing the material mixed with the base material, and a step of heat treating the dispersed solution.

Korean Patent Publication No. 2012-0023490 discloses a high stiffness composite article for shielding electromagnetic waves including (A) a thermoplastic resin, and (B) a carbon fiber having a length from 8 to 20 mm, wherein the carbon fiber (B) is included in an amount ratio from 45 to 65 wt % on the basis of the total composite. The high stiffness composite article for shielding electromagnetic waves has good mechanical strength and EMI shielding property and may replace a common magnesium material, thereby decreasing production costs with good processability.

Korean Patent Publication No. 2011-0113999 discloses a sheet composition for shielding electromagnetic waves including 50 to 70 parts by weight of a metal powder, 0.2 to 4 parts by weight of carbon nanotubes, 20 to 40 parts by weight of a binder resin and 0.5 to 20 parts by weight of a solvent on the basis of 100 parts by weight of a total composition, which has good shielding and absorbing efficiency of electromagnetic waves per unit volume in a broadband including a high frequency region and a simple manufacturing process, thereby economic.

In the above-suggested patents, a simple mixture of a carbon material such as carbon nanotubes and a metal as a shielding material of electromagnetic waves is disclosed. A metal may be easily oxidized on contact with exterior, and the above-suggested patents include such limitations.

### DISCLOSURE OF THE INVENTION

### Technical Problem

After putting forth a multilateral effort into providing a composite with a novel structure to prevent the oxidation of metal nano particles and increase electromagnetic wave shielding efficiency, a carbon composite fiber composed of metal nano particles as a core in a carbon fiber shell is manufactured via an electrospinning process, and the improvement of electromagnetic wave shielding efficiency is secured by applying the carbon composite fiber to a sheet for shielding electromagnetic waves to complete the present invention.

Another aspect of the present invention provides an electromagnetic wave shielding sheet having improved electromagnetic wave shielding efficiency and a method of manufacturing the same.

### Technical Solution

According to an embodiment, a method of manufacturing electromagnetic wave shielding sheet includes:

(step 1) preparing a first spinning solution including metal nano particles, and a second spinning solution including a carbon precursor;

(step 2) preparing a composite fiber having a web shape by injecting the first spinning solution and the second spinning solution to an electrospinning apparatus provided with a two-fluid nozzle and electrospinning, wherein the first spinning solution is injected to an inner nozzle, and the second spinning solution is injected to an outer nozzle;

(step 3) preparing a carbon composite fiber by carbonizing the composite fiber, wherein the carbon composite fiber has a core-shell structure including an outer shell formed of a carbon fiber and a core formed of metal nano particles arranged in a length direction of the carbon fiber in the outer shell; and

(step 4) forming a sheet by mixing the carbon composite fiber with a resin.

The forming of a sheet may be conducted by using the carbon composite fiber as a web shape or a pulverized and chopped carbon composite fiber shape.

In this case, the forming of a sheet may be conducted by a process of impregnating the carbon composite fiber with a resin, mixing the carbon composite fiber with a resin followed by injection molding, or mixing the carbon composite fiber with a resin followed by extrusion molding.

In addition, the first spinning solution may further include a metal precursor, a capping agent and a solvent for preparing the metal nano fiber.

According to another embodiment, an electromagnetic wave shielding sheet includes a carbon composite fiber having a core-shell structure and a resin, and the core-shell structure includes an outer shell including a carbon fiber, and a core including metal nano particles arranged in a length direction of the carbon fiber in the outer shell.

In this case, the carbon composite fiber may have a web shape or a chopped shape.

In addition, the core may further include a metal nano fiber.

### Advantageous Effects

In the electromagnetic wave shielding sheet according to the present invention, metal nano particles are provided in carbon fibers as shielding materials of electromagnetic waves to prevent the oxidation of a metal and to confirm the conductivity of the carbon fiber in a length direction.

Accordingly, a carbon composite fiber or a carbon composite fiber web including the metal nano particles and the carbon fiber has high electromagnetic wave shielding efficiency and may be used as a shielding material of electromagnetic waves in various industrial fields.

### BRIEF DESCRIPTION OF THE DRAWINGS

FIG. 1 is a schematic diagram showing a carbon composite fiber having a core-shell structure according to the present invention;

FIG. 2 is a cross-sectional view showing an electromagnetic wave shielding sheet according to an embodiment of the present invention; and

FIG. 3 is a cross-sectional view showing an electromagnetic wave shielding sheet according to another embodiment of the present invention.

[Explanation on reference numerals]

| | |
|---|---|
| 10: carbon composite fiber | 11: carbon fiber |
| 13: metal nano particles | 50, 60: sheets for shielding |
| | electromagnetic waves |
| 51: carbon composite fiber web | 53, 63: resins |
| 61: chopped carbon composite fiber | |

### MODE FOR CARRYING OUT THE INVENTION

Hereinafter, the present invention will be explained in more detail.

In the present invention, the oxidation of a metal may be prevented, and electromagnetic wave shielding efficiency may be increased further not by simply mixing metal nano particles with a carbon fiber but by making a composite having a core-shell structure via an electrospinning process.

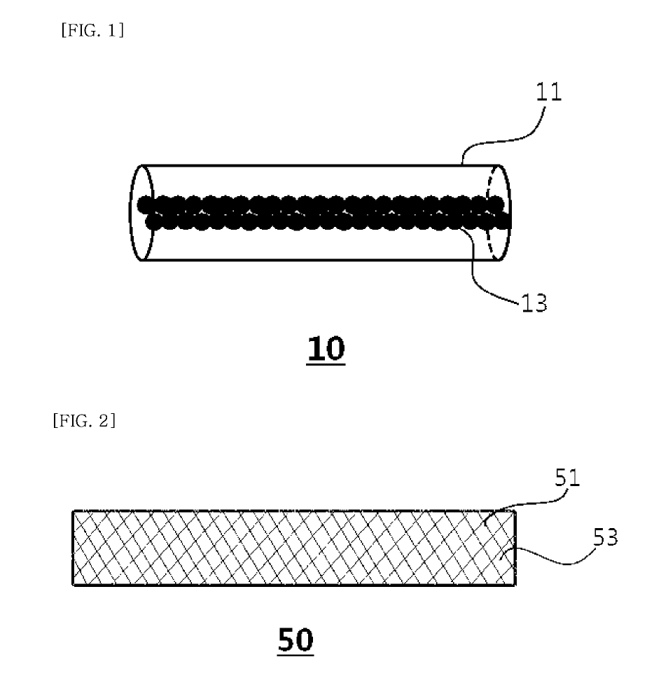

FIG. 1 is a schematic diagram showing a carbon composite fiber having a core-shell structure according to the present invention, and the carbon composite fiber 10 is composed of an outer shell 11 and a core 13.

In this case, the outer shell 11 is formed using a carbon fiber, and the core 13 is formed using metal nano particles provided in the length direction of the carbon fiber.

In the carbon composite fiber 10 having the core-shell structure, the metal nano particles of the core 13 are disposed in a length direction in the shell 13 formed using carbon fibers and are blocked from exterior. Accordingly, the oxidation of a metal may be prevented or decreased, and conductivity may be imparted in the length direction to improve electromagnetic wave shielding efficiency.

Hereinafter, “a carbon composite fiber with a core-shell structure” referred to throughout means a composite fiber composed of an outer shell formed using carbon fibers and a core formed using metal nano particles disposed in the outer shell in the length direction of the carbon fibers.

“A carbon composite fiber web” referred to throughout means “the carbon composite fiber with a core-shell structure” manufactured in a web shape.

In addition, “a chopped carbon composite fiber” referred to throughout means that “the carbon composite fiber web” is pulverized.

The carbon composite fiber may be applied to an electromagnetic wave shielding sheet and may be applied as a web shape by an electrospinning process or as a fiber shape after pulverization in many ways.

Additionally, the core may further include metal nano fibers to further increase electromagnetic wave shielding efficiency.

The a method of manufacturing electromagnetic wave shielding sheet, including the carbon composite fiber with the core-shell structure as suggested in the present invention may be manufactured by the following steps:

(step 1) preparing a first spinning solution including metal nano particles, and a second spinning solution including a carbon precursor;

(step 2) preparing a composite fiber having a web shape by injecting the first spinning solution and the second spinning solution to an electrospinning apparatus provided with a two-fluid nozzle and electrospinning, wherein the first spinning solution is injected to an inner nozzle, and the second spinning solution is injected to an outer nozzle;

(step 3) preparing a carbon composite fiber by carbonizing the composite fiber, wherein the carbon composite fiber has a core-shell structure including an outer shell formed of carbon fibers and a core formed of metal nano particles arranged in a length direction of the carbon fibers in the outer shell; and

(step 4) forming a sheet by mixing the carbon composite fiber with a resin.

Hereinafter each step will be explained in more detail.

(Step 1) Step for Preparing Spinning Solution

In this step, a first spinning solution including metal nano particles and a second spinning solution including a carbon precursor are prepared.

The first spinning solution is a solution for forming a core in a carbon composite fiber with a core-shell structure and includes metal nano particles and a dispersing solvent for dispersing hereof.

The metal nano particle is not specifically limited in the present invention, and any known material having electromagnetic wave shielding efficiency may be used. Typically, one selected from the group consisting of Al, Fe, Cr, Ni, Cu, Ag, Au, Pt, Pd, Sn, Co, stainless and combinations thereof may be used. The metal nano particles may be a single metal or an alloy of at least two metals, and may preferably be the alloy. Particularly, an alloy may be made using some kinds of metals including Cu, Fe and Ni at a high temperature of 1,000° C. or more, which is the temperature for the carbonization of a carbon fiber to prepare an Mu-metal, and the Mu-metal has permeability and becomes a material having high shielding effect.

Metal nano particles having an average particle diameter from 10 to 100 nm, and preferably, from 10 to 50 nm may be used. With the above-described size, the metal nano particles may have improved conductivity, and the electromagnetic wave shielding efficiency thereof may be increased.

As the dispersing solvent, any solvent which may disperse the metal nano particles uniformly may be used without specific limitation in the present invention. For example, one selected from the group consisting of water, methanol, ethanol, isopropyl alcohol, ethylene glycol, glycerol, perfluorodecalin, perfluoro methyldecalin, perfluorononane, perfluoroiso acid, hexane, perfluorocyclohexane, 1,2-dimethylcyclohexane, dimethylformamide (DMF), toluene, tetrahydrofuran (THF), dimethylsulfoxide, dimethylacetamide, N-methyl pyrrolidone (NMP), chloroform, methylene chloride, carbon tetrachloride, trichlorobenzene, benzene, cresol, xylene, acetone, methyl ethyl ketone, acrylonitrile, cyclohexane, cyclohexanone, ethyl ether and combinations thereof.

The second spinning solution is a solution for forming the outer shell of the carbon composite fiber with a core-shell structure and includes a carbon precursor and a solvent.

The carbon precursor may be any material capable of forming a carbon fiber after carbonization. Preferably, the carbon precursor may include one selected from the group consisting of polyacrylonitrile (PAN), polyfurfuryl alcohol, cellulose, sucrose, glucose, polyvinyl chloride, polyacrylic acid, polylactic acid, polyethylene oxide, polypyrrole, polyimide, polyimide, polyamideimide, polyaramide, polybenzylimidazole, polyaniline, polypropylene, a resorcinol-formaldehyde resin, a phenol resin, a melamine-formaldehyde resin, pitches and combinations thereof.

The solvent is not specifically limited in the present invention and may include, for example, one selected from the group consisting of N,N-dimethylformamide (DMF), dimethylacetamide (DMAc), tetrahydrofuran (THF), dimethylsulfoxide (DMSO), gamma-butyrolactone, N-methyl pyrrolidone, chloroform, toluene, acetone and combinations thereof.

In this case, the metal nano particles and the carbon precursor in the first and second spinning solutions form a core-shell forming a carbon composite fiber via subsequent processes and have a weight ratio from 1:1 to 1:100 by solid contents to confirm appropriate electromagnetic wave shielding efficiency. If the amount of the metal nano particles is less than the lower limit, the electromagnetic wave shielding efficiency owing to the metal nano particles may not be expected, and on the contrary, if the amount is greater than the upper limit, the dispersibility and the stability of the spinning solution may be deteriorated, and the preparation of a composite fiber having uniform physical properties may be difficult. Therefore, the amount may be appropriately selected within the above range.

In addition, the first spinning solution may further include a metal precursor, a capping agent and a solvent in order to include the metal fiber in the core.

The metal of the metal precursor may be the same as or different from the metal nano particles and may be one selected from the group consisting of Al, Fe, Cr, Ni, Cu, Ag, Au, Pt, Pd, Sn, Co and combinations thereof. The metal precursor may include a metal nitrate, nitride, halogenide, alkoxide, cyanine, sulfide, amide, cyanide, hydride, peroxide, porphin, hydrate, hydroxide or ester. Preferably, an Ag nano fiber may be formed using silver nitrate (AgNO₃), silver nitrite (AgNO₂), silver acetate (CH₃COOAg), silver lactate (CH₃CH(OH)COOAg), and silver citrate hydrate (AgO₂CCH₂C(OH)(CO₂Ag)CH₂CO₂Ag.xH₂O). In an embodiment of the present invention, the silver nitrate was used as the precursor for preparing the Ag nano fiber.

The capping agent is selectively adsorbed on the specific breaking face of a crystal to restrain crystal growth on the face thereof, and as a result, enables the manufacture of an Ag nano fiber with a great aspect ratio and prevents the flocculation between fibers and surface oxidation.

As the capping agent, a compound having an amine group or a carboxyl group may be used, and a polymer capping agent may be used as a material for imparting viscosity to a spinning solution during electrospinning and for forming a fiber phase during spinning in the present invention. Particularly, the polymer capping agent may form a complex during forming an Ag nano fiber and may perform a role of a reducing agent of silver cations and a viscosity increasing agent at the same time. Accordingly, a separate reducing agent and a viscosity increasing agent are not necessary except in cases of needing.

Typically, the polymer capping agent may include one selected from the group consisting of polyvinyl pyrrolidone (PVP), polyethylene oxide (PEO), polyvinyl alcohol (PVA), polyvinylidene fluoride (PVDF), polyvinyl acetate (PVAc), polyacrylionitrile (PAN), polyamide (PA), polyacrylamide (PAA), polyurethane (PU), poly(etherimide) (PEI), polybenzimidazole (PBI) and combinations thereof. For satisfactory performance as the capping agent, a polymer capping agent having a weight average molecular weight from 500,000 to 1,000,000 may be used.

In the spinning solution, the Ag precursor and the capping agent may be used in a weight ratio from 1:0.1 to 1:10 (Ag precursor:capping agent) for smooth electrospinning and the smooth formation of a nano fiber after heat treatment. If the amount of the Ag precursor is excessive, the Ag nano fiber may not be easily formed after heat treatment.

As the solvent, any solvent capable of dissolving the Ag precursor and the capping agent may be used without specific limitation, and the same solvent used for dispersing metal nano particles or a compatible solvent therewith may be used. Particular solvents may follow the above-mentioned dispersing solvents.

(Step 2) Step for Preparing Composite Fiber

In this step, the first spinning solution and the second spinning solution respectively prepared in (step 1) were injected to an electrospinning apparatus provided with a two-fluid nozzle, and an electrospinning process was performed to prepare a composite fiber with a core-shell structure.

The first spinning solution was injected to an inner nozzle, and the second spinning solution was injected to an outer nozzle, and an electrospinning process was performed to manufacture a composite fiber with a web shape.

In the present disclosure, “a composite fiber” has a core-shell structure, wherein an outer shell is formed using a carbon precursor, and an inner portion is formed as a core including metal nano particles. Additionally, the core of “the composite fiber” may further include a silver precursor and a capping agent for preparing an Ag nano fiber.

The electrospinning process is not specifically limited in the present invention and may be performed using a known electrospinning apparatus. The electrospinning apparatus includes a power supply for applying a voltage, a spinneret and a collector for collecting fibers.

A spinning solution is discharged by controlling an inflowing amount in a constant rate via the nozzle which plays the role of a spinneret. In this case, one electrode makes a connection between a voltage controlling apparatus with a nozzle tip to inject charge to the discharging spinning solution, and a counter electrode is connected to a collecting plate. Before the discharged spinning solution via the nozzle tip reaches a collector, elongation and the volatilization of a solvent may be performed to produce a composite fiber on the upper portion of the collector.

The shape of a hybrid nano fiber matrix finally obtained may be controlled according to diverse parameters including a voltage applied between the spinneret and the collector, a distance therebetween, a flowing amount of the spinning solution, the diameter of the nozzle, the position of the spinneret and the collector, etc.

A voltage between the spinneret and the collector is 5 to 50 kV, preferably, 10 to 40 kV, and more preferably, 15 to 20 kV. The voltage may give direct effect to the diameter of the composite fiber. Additionally, if the voltage increases, the diameter of the composite fiber may decrease, and the surface of the fiber may become very rough. If the voltage is too small, the manufacture of a composite fiber with the diameter of from nm to μm is difficult. Accordingly, the voltage is controlled appropriately within the above-described range.

In addition, since the diameter of the spinneret decreases, the diameter of the composite fiber may decrease, a spinneret with the diameter from 0.01 to 1 mm for a core and from 0.05 to 3 mm for exterior may be used to manufacture a composite fiber having a diameter of a nm level with uniform surface.

The electrospinning process may be performed with a voltage from 5 to 50 kV between the spinneret and the collector, which may be disposed with a distance from 5 to 20 cm, with a flowing amount of a spinning solution from 0.05 to 5 ml/h, and with the diameter of the spinneret from 0.01 to 1 mm for a core and from 0.05 to 3 mm for exterior, to produce a composite fiber with a core-shell structure having a diameter from nm to μm, and preferably, from 10 to 1,000 nm.

(Step 3) Step for Manufacturing Carbon Composite Fiber with Core-Shell Structure

In this step, the composite fiber manufactured in (step 2) may be carbonized to manufacture a carbon composite fiber.

In this case, the composite fiber of (step 2) may be formed as a web shape, and the carbon composite fiber manufactured by carbonizing thereof may also have a web shape.

The carbonization is performed to manufacture a common carbon fiber, and a carbonization process is not specifically limited in the present invention. Preferably, the carbonization process is performed by heat treating at from 500° C. to about 3,000° C. for from 20 minutes to 5 hours. By the carbonization, all organic materials (in addition to a solvent, a capping agent, a resin, an additive, etc.) present in the composite fiber are removed, and carbon atoms are rearranged or make adhered to form a carbon structure with good conductivity, that is, a carbon fiber.

The carbon fiber thus obtained has a diameter from 1 nm to 100 μm, and preferably, from 100 nm to 10 μm. If the temperature or the time is less than the lower limit, the formation of the carbon fiber may be difficult.

The carbon composite fiber obtained by the carbonization has a core-shell structure composed of an outer shell formed using carbon fibers and a core formed using metal nano particles disposed in the length direction of the carbon fibers in the outer shell.

In addition, the metal nano fibers of the core are manufactured by the carbonization process by adding a metal precursor, etc. to the first spinning solution. The metal nano fiber thus manufactured has a diameter from 10 to 1,000 nm.

(Step 4) Step of Forming Sheet

In this step, the forming of a sheet of the carbon composite fiber manufactured in (step 3) with a resin is performed to manufacture electromagnetic wave shielding sheet.

The carbon composite fiber manufactured via (step 3) has a web shape, and the carbon composite fiber having the web shape may be applied to the sheet as it is for shielding electromagnetic waves, or a carbon composite fiber having a chopped shape obtained via the pulverization thereof may be applied to the sheet for shielding electromagnetic waves.

The sheet forming process is not specifically limited in the present invention, and any method for manufacturing a sheet known in this art may be used.

Typically, the carbon composite fiber may be impregnated with a resin, mixed with a resin and then, injection molded, or mixed with a resin and then, extrusion molded. In an embodiment, an impregnation process may be performed by making a frame using a mold, filling a resin in the frame, injecting a composite fiber web, and impregnating again with a thermoplastic resin. In this case, a casting method may be used for pressurization or for a uniform thickness.

Any resin used as a matrix of a sheet for shielding electromagnetic waves may be used without specific limitation in the present invention. Preferably, one selected from the group consisting of a polyamide-based resin, a polyester-based resin, a polyacetal-based resin, a polycarbonate-based resin, a poly(meth)acrylate-based resin, a polyvinyl chloride-based resin, a polyether-based resin, a polysulfide-based resin, a polyimide-based resin, a polysulfone-based resin, a polyolefine-based resin, an aromatic vinyl-based resin and combinations thereof may be used.

The resin solution may use a solvent selected from the group consisting of dimethylformamide (DMF), toluene, tetrahydrofuran (THF), dimethyl sulfoxide, dimethylacetamide, N-methyl pyrrolidone (NMP), chloroform, methylene chloride, carbon tetrachloride, trichlorobenzene, benzene, cresol, xylene, acetone, methyl ethyl ketone, acrylonitrile, cyclohexane, cyclohexanone, ethyl ether, hexane, isopropyl alcohol, methanol, ethanol and combinations thereof.

As described above, various sheets for shielding electromagnetic waves may be manufactured according to the shapes of the carbon composite fiber or processing methods.

FIG. 2 is a cross-sectional view showing an electromagnetic wave shielding sheet according to a first embodiment of the present invention, and an electromagnetic wave shielding sheet 50 manufactured by a first embodiment has a structure in which a carbon composite fiber 51 is impregnated with a resin 53.

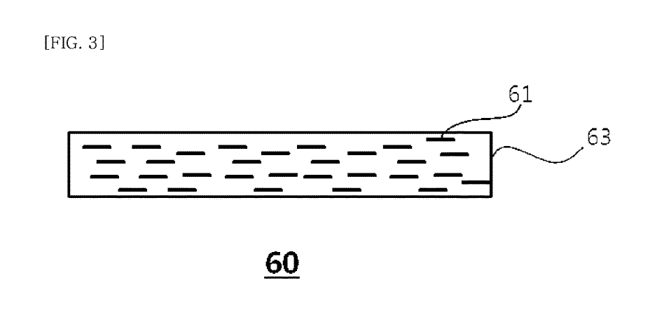

FIG. 3 is a cross-sectional view showing an electromagnetic wave shielding sheet according to another embodiment of the present invention, and an electromagnetic wave shielding sheet 60 manufactured by a second embodiment has a structure including a resin matrix 63 and a chopped carbon composite fiber 61 dispersed in the matrix 63.

The demand prospect of the electromagnetic wave shielding sheet suggested in the present invention is very bright according to the construction of a facility for shielding electromagnetic waves in general constructions such as general offices and houses as well as in medical facilities such as a hospital, industrial facilities and military facilities worrying the harm damage of the malfunction of precision instruments due to electromagnetic waves. Therefore, the method and the sheet for shielding electromagnetic waves obtained thereby according to the present invention have the following merits.

First, by disposing metal nano particles inside, the oxidation of a metal may be prevented, and conductivity may be confirmed. In addition, since the surface layer of a metal may be easily oxidized, and an oxide may be formed, mechanical strength may be deteriorated, and the shielding property of electromagnetic radio frequency interference (EMI)/radio frequency interference may be deteriorated. However, by using a material for shielding and absorbing electromagnetic waves of the present invention, the surface oxidation may not be generated, and the deterioration of the shielding property of electromagnetic waves may not be generated.

Second, the carbon composite fiber having a core-shell structure may be applied with a web shape just as it is, or may be pulverized and allowed to undergo various processes with a resin to manufacture a sheet for shielding electromagnetic waves. That is, the carbon composite fiber may be applied as various shapes such as a web shape or a chopped shape according to the field for application.

Third, the carbon composite fiber having a core-shell structure may be easily manufactured by an electrospinning process, and the network structure of a fiber web thus obtained may assure high shielding efficiency.

Fourth, desired physical properties as a sheet for shielding electromagnetic waves may be obtained by controlling the mixing ratio of a metal nano material and a resin added.

Particularly, by performing an electrospinning process for the manufacture of the sheet for shielding electromagnetic waves, the process may be easily controlled, and the physical properties of the product thus manufactured may be controlled. Therefore, shielding reliability as a sheet for shielding electromagnetic waves and productivity may be good.

Hereinafter the present invention will be explained in more detail with reference to exemplary embodiments. However, it is obvious to a person skilled in the art that the embodiments are for particular explanation of the present invention, and the scope of the present invention is not limited to the following embodiments. Therefore, the scope of the present invention should not be interpreted to be limited to the following embodiments.

### Example 1: Manufacturing Sheet for Shielding Electromagnetic Waves Through Impregnation of Composite Fiber Web

As a first spinning solution, a solution (for core) was prepared by mixing ethanol with 5 g of Cu having a particle size from 20 to 40 nm, and as a second spinning solution, a 12% PAN solution dissolved in DMF (for exterior) was prepared.

The first and second spinning solutions were positioned in syringe pumps connected to the inner and outer sides of a two-fluid nozzle and were fixed to a flow rate of 0.005 ml/h. In this case, a collector and a spinneret were positioned in a perpendicular relation, and the collector was prepared by designing using a conductive metal electrode. The distance between the spinneret and the collector was fixed to 15 cm, and a voltage of 15 kV was applied to form a composite fiber (with a diameter from 100 to 500 nm) having a web shape.

The composite fiber was injected to a furnace, and a carbonization process was performed for 3 hours to manufacture a core-shell carbon composite fiber (Cu/CNF) having a web shape.

The core-shell carbon composite fiber with a web shape thus obtained was impregnated with polymethylmethacrylate (PMMA)/DMF (with a concentration of 10 wt %), and dried at a temperature range from room temperature to 80° C. for 24 hours to manufacture a sheet for shielding electromagnetic waves.

### Example 2: Manufacturing by Molding Sheet Using Chopped Composite Fiber

The core-shell carbon composite fiber having a web shape manufactured in Example 1 was pulverized using a chopping machine to a length from 0.001 to 1 mm. The chopped composite fiber thus obtained was mixed with polymethylmethacrylate (PMMA) in a weight ratio of 1:3 and pressurized to manufacture a sheet for shielding electromagnetic waves via a sheet molding process.

### Example 3: Manufacturing Sheet for Shielding Electromagnetic Waves Including Ag Nano Fiber in Core

A sheet for shielding electromagnetic waves was manufactured by performing the same procedure described in Example 1 except for forming a core-shell carbon composite fiber (Cu, Ag/CNF) using a solution obtained by mixing 10 ml of an ethanol solution including 3 g of AgNO₃ and 0.5 g of PVP with 5 g of Cu having a particle size from 20 to 40 nm as the first spinning solution, and performing an impregnation process.

### Example 4: Manufacturing by Molding Sheet Using Chopped Composite Fiber

The core-shell carbon composite fiber (Cu, Ag/CNF) obtained in Example 3 was pulverized using a chopping machine to a length from 0.001 to 1 mm. The chopped composite fiber thus obtained was mixed with polymethylmethacrylate (PMMA) in a weight ratio of 1:3 and pressurized to manufacture a sheet for shielding electromagnetic waves via a sheet molding process.

### Comparative Example 1: Manufacturing Sheet for Shielding Electromagnetic Waves Via Simple Mixing Process

A sheet for shielding electromagnetic waves was manufactured by mixing 500 ml of DMF, 100 g of PMMA and 5 g of Cu having a particle size from 20 to 40 nm and molding a sheet.

### Comparative Example 2: Manufacturing Sheet for Shielding Electromagnetic Waves Via Simple Mixing Process

A sheet for shielding electromagnetic waves was manufactured by mixing 500 ml of DMF, 100 g of PMMA, 5 g of Cu having a particle size from 20 to 40 nm, and 2 g of CNF (with a diameter from 10 to 20 nm and a length from 1 to 2 cm) and molding a sheet.

### Experimental Example 1: Measuring EMI Shielding Property

The EMI shielding property of the sheets for shielding electromagnetic waves obtained by the above method was measured, and the results are shown in Table 1.

In this case, EMI shielding property (dB) was obtained by measuring shielding property of electromagnetic waves at the EMI of 1 GHz for samples (6×6) having a thickness of 100 μm.

TABLE 1

| | Fiber | Shape | EMI shielding property |
|---|---|---|---|
| Example 1 | Cu/CNF | Web | 55 |
| Example 2 | Cu, CNF | Chopped | 50 |
| Example 3 | Cu, Ag/CNF | Web | 59 |
| Example 4 | Cu, Ag/CNF | Chopped | 57 |
| Comparative | Cu | — | 22 |
| Example 1 | | | |
| Comparative | Cu, CNF | | 25 |
| Example 2 | | | |

As shown in Table 1, the CMI shielding property of the sheet for shielding electromagnetic waves manufactured by electrospinning according to the present invention is better than that manufactured by simple mixing.

1. A method of manufacturing electromagnetic wave shielding sheet, the method comprising:
(step 1) preparing a first spinning solution comprising metal nano particles, and a second spinning solution comprising a carbon precursor;
(step 2) preparing a composite fiber having a web shape by injecting the first spinning solution and the second spinning solution to an electrospinning apparatus provided with a two-fluid nozzle and electrospinning, the first spinning solution being injected to an inner nozzle, and the second spinning solution being injected to an outer nozzle;
(step 3) preparing a carbon composite fiber by carbonizing the composite fiber, the carbon composite fiber having a core-shell structure comprising an outer shell formed of a carbon fiber and a core formed of metal nano particles arranged in a length direction of the carbon fiber in the outer shell; and
(step 4) forming a sheet by mixing the carbon composite fiber with a resin.

2. The method of manufacturing electromagnetic wave shielding sheet of claim 1, wherein the first spinning solution further comprises a metal precursor, a capping agent and a solvent for preparing the metal nano fiber.

3. The method of manufacturing electromagnetic wave shielding sheet of claim 2, wherein the metal precursor is an oxide, a nitride, a halogenide, an alkoxide, a cyanine, a sulfide, an amide, a cyanide, a hydride, a peroxide, a porphin, a hydrate, a hydroxide or an ester including a metal selected from the group consisting of Al, Fe, Cr, Ni, Cu, Ag, Au, Pt, Pd, Sn, Co and combinations thereof.

4. The method of manufacturing electromagnetic wave shielding sheet of claim 2, wherein the capping agent is one selected from the group consisting of polyvinyl pyrrolidone (PVP), polyethylene oxide (PEO), polyvinyl alcohol (PVA), polyvinylidene fluoride (PVDF), polyvinyl acetate (PVAc), polyacrylonitrile (PAN), polyamide (PA), polyacrylamide (PAA), polyurethane (PU), poly(etherimide) (PEI), polybenzimidazole (PBI) and combinations thereof.

5. The method of manufacturing electromagnetic wave shielding sheet of claim 1, wherein the carbon precursor comprises one selected from the group consisting of polyacrylonitrile (PAN), polyfurfuryl alcohol, cellulose, sucrose, glucose, polyvinyl chloride, polyacrylic acid, polylactic acid, polyethylene oxide, polypyrrole, polyimide, polyimide, polyamideimide, polyaramide, polybenzylimidazole, polyaniline, polypropylene, a resorcinol-formaldehyde resin, a phenol resin, a melamine-formaldehyde resin, pitches and combinations thereof.

6. The method of manufacturing electromagnetic wave shielding sheet of claim 1, wherein the metal nano particles and the carbon precursor has a weight ratio from 1:1 to 1:100.

7. The method of manufacturing electromagnetic wave shielding sheet of claim 1, wherein the electrospinning is conducted with a voltage from 5 to 50 kV between a spinneret and a collector, the spinneret and the collector being spaced apart by 5 to 20 cm, a flowing rate of a spinning solution being from 0.05 ml/h to 5 ml/h, and a diameter of the spinneret being from 0.01 to 1 mm for a core and from 0.05 to 3 mm for an exterior.

8. The method of manufacturing electromagnetic wave shielding sheet of claim 1, wherein the forming of a sheet is conducted by using the carbon composite fiber as a web shape or a pulverized and chopped carbon composite fiber shape.

9. The method of manufacturing electromagnetic wave shielding sheet of claim 1, wherein the forming of a sheet is conducted by a process of impregnating the carbon composite fiber with a resin, mixing the carbon composite fiber with a resin followed by injection molding, or mixing the carbon composite fiber with a resin followed by extrusion molding.
